(19) United States
(12) Patent Application Publication
(10) Pub. No.: US 2015/0311035 A1
(43) Pub. Date: Oct. 29, 2015

(54) LITHOGRAPHY APPARATUS, AND METHOD OF MANUFACTURING AN ARTICLE

(71) Applicant: CANON KABUSHIKI KAISHA, Tokyo (JP)

(72) Inventor: Hiro Norikane, Utsunomiya-shi (JP)

(21) Appl. No.: 14/695,391

(22) Filed: Apr. 24, 2015

(30) Foreign Application Priority Data
Apr. 28, 2014 (JP) 2014-093166

(51) Int. Cl. H01J 37/302; H01J 37/04; H01J 37/317

(52) U.S. Cl. CPC H01J 37/3023; H01J 37/3174; H01J 37/045; H01J 2237/0435

(57) ABSTRACT

The present invention provides a lithography apparatus that performs patterning on a substrate with a beam, the apparatus comprising a blanker configured to perform blanking of the beam, and a controller configured to control the blanker based on a quantized value of dose with respect to each of pixels on the substrate, wherein the controller is configured to determine the quantized value of dose with respect to each of the pixels based on an error between a target value of dose and each of a plurality of predicted values of dose that are based on a plurality of quantized values of dose.

### BACKGROUND OF THE INVENTION

1. Field of the Invention

The present invention relates to a lithography apparatus, and a method of manufacturing an article.

2. Description of the Related Art

As circuit patterns in semiconductor integrated circuits have become finer and more highly integrated, attention has been given to drawing apparatuses that form a pattern (latent pattern) on a substrate using a charged particle beam (electron beam). In drawing apparatuses, the spatial modulation method is used as a method for controlling the dose with respect to pixels on the substrate. The spatial modulation method is a method in which drawing is performed on a substrate by, for example, binarizing the target values of doses for pixels expressed by a large number of tones (gradation or gray scale pixels), and controlling the switching on and off of the charged particle beam at the pixels based on the binarized information.

In this spatial modulation method, error can arise between the binarized dose values and the target values. For this reason, Japanese Patent Laid-Open No. 2012-527764 proposes a method in which, while successively performing binarization on pixels, the binarization-related error arising at the target pixel is diffused into the target value of the subsequent pixel adjacent to the target pixel.

In drawing apparatuses, operating lag (operating delay) generally occurs in the blanker when the charged particle beam is switched on and off. For this reason, the actual dose on the substrate can differ from the planned dose. The method disclosed in Japanese Patent Laid-Open No. 2012-527764 is therefore not sufficient in terms of the fidelity of pattern formation (patterning).

### SUMMARY OF THE INVENTION

The present invention provides, for example, a technique that is advantageous in terms of fidelity of patterning.

According to one aspect of the present invention, there is provided a lithography apparatus that performs patterning on a substrate with a beam, the apparatus comprising: a blanker configured to perform blanking of the beam; and a controller configured to control the blanker based on a quantized value of dose with respect to each of pixels on the substrate, wherein the controller is configured to determine the quantized value of dose with respect to each of the pixels based on an error between a target value of dose and each of a plurality of predicted values of dose that are based on a plurality of quantized values of dose.

Further features of the present invention will become apparent from the following description of exemplary embodiments with reference to the attached drawings.

### BRIEF DESCRIPTION OF THE DRAWINGS

FIG. 1 is a schematic diagram showing a drawing apparatus.

FIG. 2A is a diagram showing paths on a substrate in the scanning of charged particle beams.

FIG. 2B is a diagram showing paths on a substrate in the scanning of charged particle beams.

FIG. 3 is a diagram showing a positional relationship between an objective lens array and stripe areas.

FIG. 4 is a diagram showing a configuration of blankers.

FIG. 5 is a diagram for describing a spatial modulation drawing method.

FIG. 6 is a diagram showing an example of a relationship between dose command values at pixels and actual irradiation doses at pixels.

FIG. 7 is a diagram showing a flow of data in the drawing apparatus.

FIG. 8 is a flowchart of binarization processing.

FIG. 9 is a diagram for describing binarization processing.

FIG. 10 is a diagram showing a look-up table.

FIG. 11 is a diagram for describing binarization processing.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given. Also, although a drawing apparatus that forms a pattern on a substrate by irradiating the substrate with charged particle beams serving as the beams is described in the following embodiments, the present invention is not limited to this. For example, the present invention can also be applied to a lithography apparatus such as an exposure apparatus that exposes a substrate using light (a light beam) as the beam.

### First Embodiment

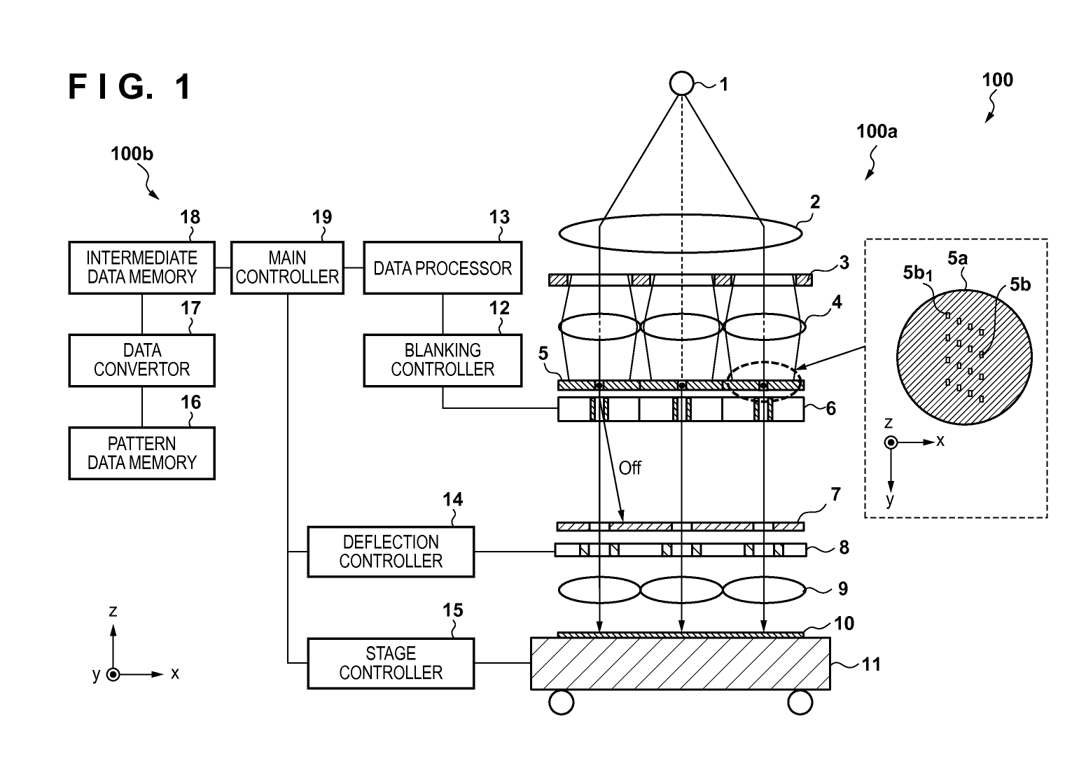

A drawing apparatus 100 of a first embodiment of the present invention will be described below with reference to FIG. 1. The drawing apparatus 100 of the first embodiment can include a drawing unit 100a that forms a pattern on a substrate 10 by drawing on the substrate 10 using charged particle beams, and a controller 100b that controls units of the drawing unit 100a, for example.

The drawing unit 100a will be described first. The drawing unit 100a can include a charged particle source 1, a collimator lens 2, a first aperture array 3, condenser lenses 4, a second aperture array 5, a blanker array 6, a blanking aperture 7, a deflector array 8, and an objective lens array 9, for example. The drawing unit 100a can also include a movable stage 11 that holds the substrate 10.

The charged particle source 1 can be a thermionic emission electron source that includes an electron emission material such as LaB6 or BaO/W, for example. The collimator lens 2 is an electrostatic lens for condensing a charged particle beam using an electrical field, for example, and is used for forming the charged particle beam emitted from the charged particle source 1 into a parallel beam, and causing the parallel beam to be incident on the first aperture array 3. The first aperture array 3 has multiple openings arranged in a matrix, and divides the incident parallel charged particle beam into multiple beams. The divided charged particle beams obtained by the first aperture array 3 pass through the condenser lenses 4 and are then incident on the second aperture array 5. The second aperture array 5 includes multiple sub arrays 5a that each include multiple openings. The sub arrays 5a are arranged so as to correspond to the divided charged particle beams obtained by the first aperture array 3, and further divide the charged particle beams to generate charged particle beams. In the first embodiment, each sub array 5a has 16 (4×4) openings 5b, for example, and can further divide a divided charged particle beam obtained by the first aperture array 3 into 16 (4×4) charged particle beams.

The divided charged particle beams obtained by the sub arrays 5a in the second aperture array 5 are caused to be incident on the blanker array 6, which includes blankers that individually deflect the charged particle beams. The blankers included in the blanker array 6 each include two opposing electrodes, for example, and can deflect a charged particle beam by generating an electrical field by applying a voltage between the two electrodes. The charged particle beams deflected by the blanker array 6 do not arrive at the substrate 10 due to being blocked by the blanking aperture 7 arranged downstream of the blanker array 6. On the other hand, the charged particle beams not deflected by the blanker array 6 pass through openings formed in the blanking aperture 7 and arrive at the substrate 10. In other words, the blanker array 6 switches between irradiation (ON) and non-irradiation (off) of the substrate 10 with the charged particle beams. The charged particle beams that pass through the blanking aperture 7 are incident on the deflector array 8, which is for scanning the substrate with the charged particle beams. The deflector array 8 includes multiple deflectors, and the deflectors deflect the charged particle beams all together in the X direction (scanning direction) for example, in parallel with the deflection of the charged particle beams by the blankers in the blanker array 6. Accordingly, the substrate can be scanned with the charged particle beams that passed through the objective lens array 9. Although the deflector array 8 shown in FIG. 1 includes deflectors that are in one-to-one correspondence with the sub arrays 5a, the present invention is not limited to this, and a configuration is possible in which each deflector corresponds to multiple sub arrays 5a, for example. Also, the stage 11 is configured to hold the substrate 10 by an electrostatic chuck or the like, and to be able to move the substrate 10 in the X and Y directions.

Next, the controller 100b will be described. The controller 100b can include a blanking controller 12, a data processor 13, a deflection controller 14, a stage controller 15, a pattern data memory 16, a data convertor 17, an intermediate data memory 18, and a main controller 19, for example. The blanking controller 12 individually controls the blankers included in the blanker array 6. The data processor 13 has a buffer memory for storing intermediate data, and generates control data for control of the blanker array 6 by the blanking controller 12, based on the stored intermediate data. The deflection controller 14 controls the deflector array 8. The stage controller 15 controls the positioning of the stage 11 based on signals from a measuring instrument (not shown) that measures the position of the stage 11. The measuring instrument can include a laser interferometer, for example.

The pattern data memory 16 stores design data (pattern data) defining a pattern that is to be drawn on the substrate. The data convertor 17 divides the design data stored in the pattern data memory into units of stripes, and performs conversion into intermediate data in order to make the drawing processing easier to perform. A stripe is an area drawn by multiple charged particle beams in the drawing unit 100a by scanning the stage 11 one time in a predetermined direction (e.g., the Y direction), for example. The intermediate data memory 18 stores the converted intermediate data obtained by the data convertor 17. The main controller 19 transfers intermediate data to the buffer memory of the data processor 13 according to the pattern that is to be drawn, and performs overall control of the drawing apparatus 100 by controlling the above-described controllers, processors, and the like. Note that these constituent elements included in the controller 100b of the first embodiment are merely one example, and can be changed as appropriate.

The following describes an example of a raster scan drawing method used by the drawing apparatus 100 having the above configuration. Charged particle beams are scanned over a scanning grid on the substrate that is determined by the position of the stage 11 and the deflection performed by the deflector array 8, and the switching on and off of the charged particle beams on the substrate is controlled by the blanker array 6 according to the pattern that is to be drawn on the substrate. This scanning grid is a grid defined by a pitch GX in the X direction and a pitch GY in the Y direction, and the elements constituting the grid defined by the pitch GX and the pitch GY correspond to the smallest dot that can be drawn by one charged particle beam (i.e., correspond to a pixel). The controller 100b deflects charged particle beams using the deflector array 8 so as to scan the substrate in the X direction, while successively moving the substrate 10 in the Y direction using the stage 11. In parallel with deflecting the charged particle beams in the X direction using the deflector array 8, the controller 100b uses the blanker array 6 to control the switching on and off of the charged particle beams for each pixel defined by the pitch GX.

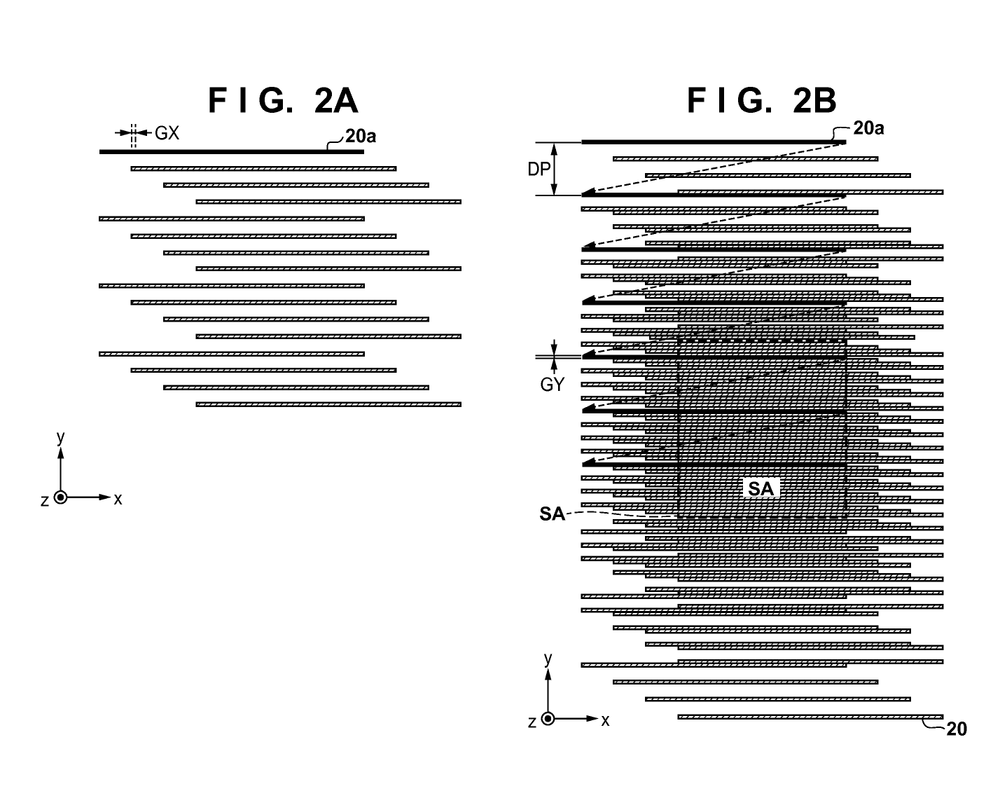

FIGS. 2A and 2B are diagrams showing paths on the substrate in the scanning of 4×4 divided charged particle beams obtained by one sub array 5a. FIG. 2A is a diagram showing areas 20 on the substrate in which charged particle beams perform drawing when the 4×4 charged particle beams are deflected in the X direction one time by the deflector array 8. FIG. 2B is a diagram showing the range (a stripe area SA) in which the 4×4 charged particle beams can perform drawing due to the deflection of the charged particle beams by the deflector array 8 and the movement of the substrate 10 by the stage 11. Although FIGS. 2A and 2B show the case in which the substrate 10 is irradiated with the charged particle beams the entire time, in actuality, the switching on and off of the charged particle beams is controlled by the blanker array 6 for each pixel defined by the pitch GX, as previously described.

In FIG. 2B, a solid black area 20a is an area 20 that is drawn when a charged particle beam that passed through an opening 5b₁ formed in the sub array 5a is deflected by the deflector array 8. The charged particle beam that passed through the opening 5b₁ first draw the uppermost area 20a, and then, as shown by the dashed line arrows, successively draws areas 20a due to fly-back in the −X direction and the movement of the stage 11 in the −Y direction (distance DP). At this time, the charged particle beams that passed through openings 5b other than the opening 5b₁ also draw areas on the substrate 10 similarly to the charged particle beams that passed through the opening 5b₁. Accordingly, the stripe area SA having a stripe width SW can be filled in by the areas 20 drawn by the charged particle beams as shown by the dashed lines in FIG. 2B. In other words, the drawing apparatus 100 can draw the stripe area SA by repeatedly performing successive movement of the stage 11 and deflection of the charged particle beams using the deflector array 8. This stripe area SA is the area on the substrate that can be drawn by the charged particle beams that passed through one sub array 5a.

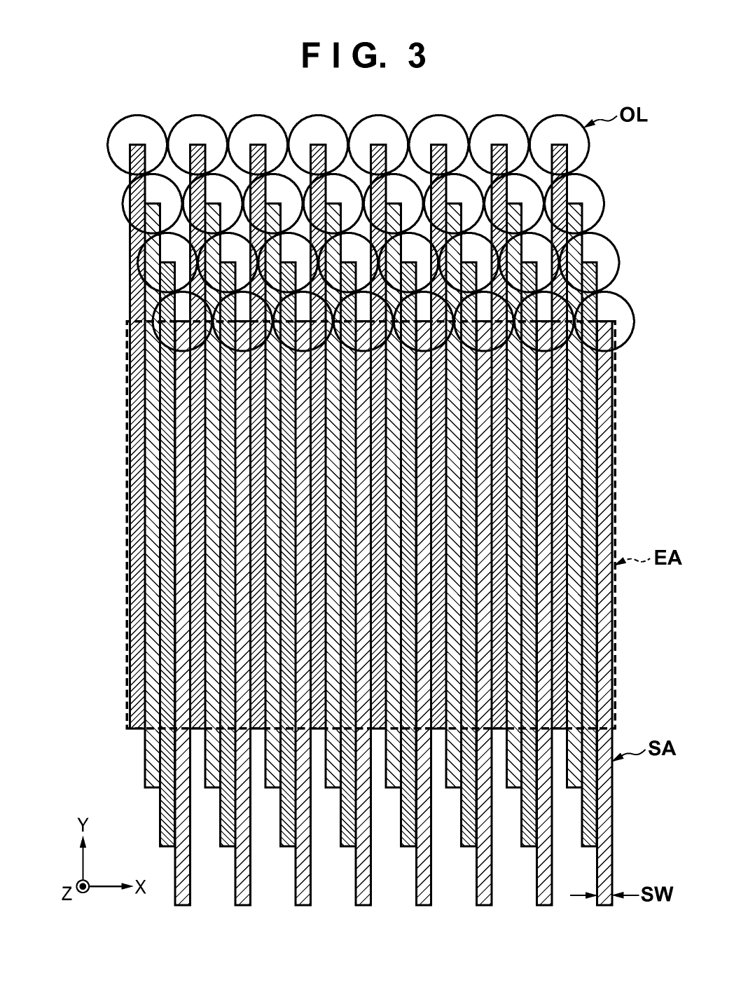

FIG. 3 is a diagram showing the positional relationship between objective lenses OL of the objective lens array 9 and stripe areas SA. As described above, one stripe area SA is the area on the substrate that can be drawn by divided charged particle beams obtained by one sub array 5a. Also, the divided charged particle beams obtained by one sub array 5a pass through one objective lens OL in the objective lens array 9. As shown in FIG. 3, the objective lens array 9 is configured such that, for example, each row of objective lenses includes multiple objective lenses OL aligned with a pitch of 130 μm in the X direction, and multiple rows of objective lenses are arranged side-by-side in the Y direction while being shifted by 2 μm, which is the stripe width SW, from each other in the X direction. Configuring the objective lens array 9 in this way makes it possible to arrange multiple stripe areas SA with no space therebetween. Although the objective lens array 9 is configured by 4×8 objective lenses OL in FIG. 3, in actuality, it can be configured by a large number of objective lenses OL, such as 65×200 lenses. According to this configuration, drawing can be performed on the substrate in a drawing area EA by successively moving the stage 11 toward one side in the Y direction.

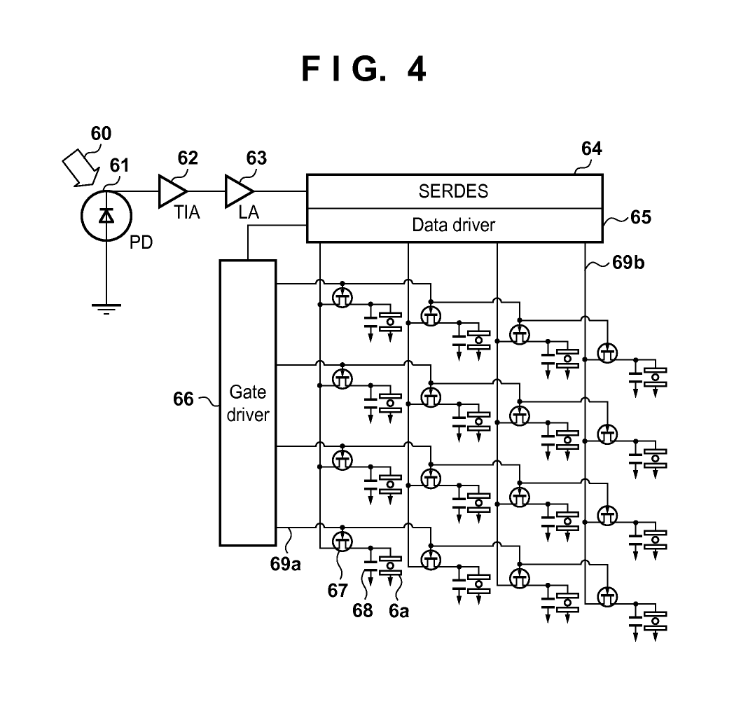

Next, deflection of the charged particle beams in the blanker array 6 will be described with reference to FIG. 4. FIG. 4 is a diagram showing the configuration of blankers 6a that individually deflect the divided charged particle beams obtained by one sub array 5a (having 4×4 openings 5b, for example). A signal indicating control data is supplied as a light signal 60 from the blanking controller 12 to the blankers 6a, for example. The supplied light signal 60 is received by a photodiode (PD) 61 and supplied to a transfer impedance amplifier (TIA) 62 as an electrical signal. The signal supplied to the TIA is subjected to current-voltage conversion in the TIA, and then the amplitude of the resulting signal is adjusted in a limiting amplifier (LA) 63. The signal resulting from amplitude adjustment is input to a shift register 64 and converted into signals for applying voltages to the blankers (parallel signals). Gate electrode lines 69a extending in the X direction and source electrode lines 69b extending in the Y direction are respectively connected to gate electrodes and source electrodes of FETs 67 arranged at intersections between these lines. One blanker 6a and one capacitor 68 are connected in parallel to the drain electrode of each FET 67, and the opposite sides of these two elements are grounded.

For example, when a gate driver 66 supplies a signal (voltage) to one gate electrode line 69a, all of the FETs 67 in the one row connected to that gate electrode line 69a are switched on. At this time, the voltages applied to the source electrode lines 69b are applied to the blankers 6a, and the capacitors 68 connected to the switched-on FETs 67 accumulate (become charged with) charges corresponding to the voltages applied to the source electrode lines. When the charging of one row of capacitors 68 ends, the gate driver 66 switches the gate electrode line 69a to which the voltage is applied. At this time, the aforementioned one row of blankers 6a lose the voltage from the source electrode line 69b, but can maintain a necessary voltage until the next voltage application due to the charges accumulated in the capacitors 68. In this way, with an active matrix driving method using the FETs 67 as switches, voltages can be applied to a large number of blankers 6a in parallel using the gate electrode lines 69a and the source electrode lines 69b. For this reason, it is possible to handle an increase in the number of blankers 6a with a small number of wires. In the example in FIG. 4, the blankers 6a are arranged in four rows and four columns. The parallel signals from the shift register 64 are applied as voltages to the source electrodes of the FETs 67 via a data driver 65 and the source electrode lines 69b. In conjunction with this, one row of FETs 67 is switched on by the voltage applied by the gate driver 66, and thus the one row of connected blankers 6a is controlled. The four rows and four columns of blankers 6a can be controlled by successively repeating the above operation on each row.

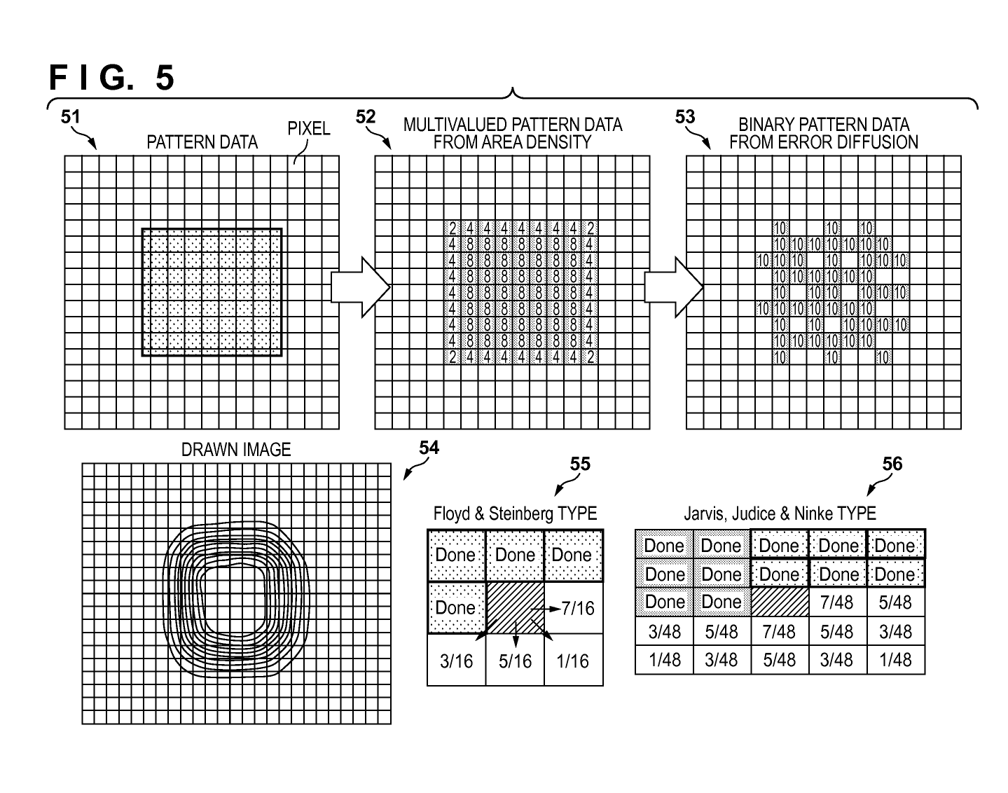

FIG. 5 is a diagram for describing a spatial modulation drawing method. In the following description, “10” is used as the charged particle beam irradiation dose for one pixel, and “8” is used as the maximum dose target value for one pixel. In FIG. 5, 51 indicates a diagram in which design data (pattern data) defining a pattern that is to be drawn on a substrate is arranged on the scanning grid of the drawing apparatus 100. The pattern data indicated by 51 in FIG. 5 is a 20 nm×20 nm square formed by design grid points with a pitch of 0.25 nm. The inter-pixel pitch in the scanning grid is 2.5 nm, and since this is larger than the pitch of the design grid, the pattern data cannot be faithfully expressed on the scanning grid, as shown in this figure. In view of this, the controller 100b calculates the area density of the pattern data at each pixel, and determines a target value for the dose (exposure amount) at each pixel based on the corresponding area density. Specifically, using the pattern data, the controller 100b determines a target value for the charged particle beam dose according to the percentage of area that the pattern occupies in the pixel that is to be irradiated with charged particle beams (pattern occupancy (occupancy rate)). Accordingly, as shown by 52 in FIG. 5, the controller 100b can generate multivalued pattern data expressing target values for charged particle beam doses at the pixels.

Then, in order to generate command values indicating the switching on or off of the charged particle beams at the pixels, the controller 100b converts the multivalued pattern data into binary pattern data using an error diffusion method for example. For example, conventionally, for each pixel in the multivalued pattern data indicated by 52 in FIG. 5, the controller 100b sets the command value to “0” if the target value at the pixel is less than a threshold value (e.g., “5”), and sets the command value at the pixel to “10” if the target value is greater than or equal to the threshold value. In other words, the charged particle beam is switched off at a pixel for which the command value is set to “0”, and the charged particle beam is switched on at a pixel for which the command value is set to “10”. The controller 100b then distributes error between the command value and the target value to neighboring pixels with percentages determined by the error diffusion kernel indicated by 55 in FIG. 5. By repeating these processes in raster scan order from the top left pixel to the bottom right pixel, the controller 100b can generate binary pattern data as indicated by 53 in FIG. 5. In FIG. 5, 54 indicates a drawn image obtained by controlling the switching on and off of charged particle beams based on the binary pattern data indicated by 53 in FIG. 5. Here, the beam diameter of the charged particle beams is sufficiently larger than the 2.5 nm×2.5 nm pixels, and the pattern of coarseness/fineness on the grid is smoothened. Also, although the controller 100b performs binarization using the Floyd & Steinberg error diffusion method kernel indicated by 55 in FIG. 5, the present invention is not limited to this. For example, another kernel such as the Jarvis, Judice & Ninke error diffusion method kernel indicated by 56 in FIG. 5 may be used.

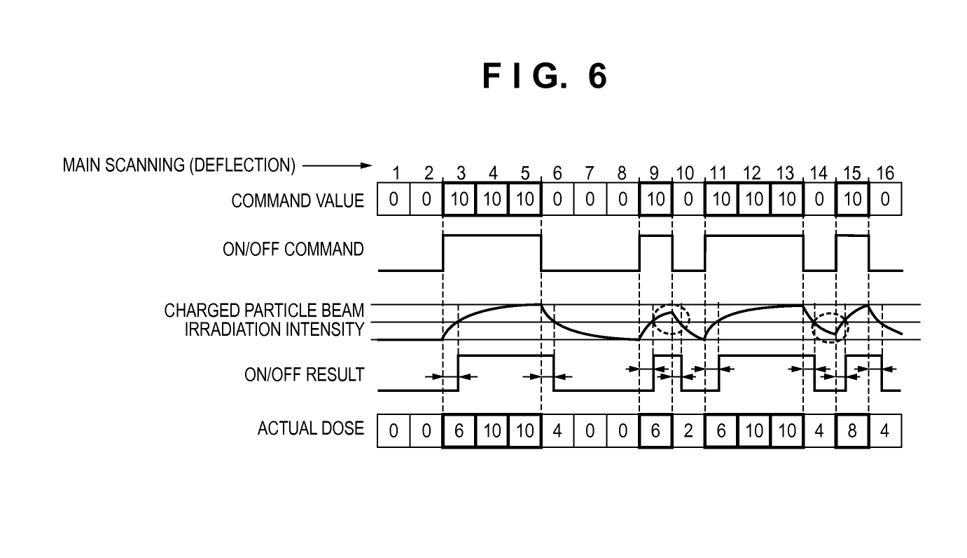

FIG. 6 is a diagram showing an example of the relationship between dose command values at pixels and actual irradiation doses (actual doses) at pixels. The command values are expressed by quantized values obtained by quantizing the target values. In the first embodiment, an example is described in which binarized values (“0” or “10”) indicating the switching on or off of charged particle beams at the pixels defined by the binary pattern data are used as the quantized values. As previously described, the charged particle beams are switched off at pixels set to “0”, and the charged particle beams are switched on at pixels set to “10”. FIG. 6 shows one line worth of binary pattern data.

The controller 100b controls the blanker array 6 in accordance with the binary pattern data. For example, at a pixel for which the command value is set to “10”, a voltage is not applied to the two electrodes at the blanker 6a, and the charged particle beam passes through the blanking aperture 7 and is incident on the substrate 10 without being deflected by the blanker 6a. On the other hand, at a pixel for which the command value is set to “0”, a voltage is applied to the two electrodes at the blanker 6a, and the charged particle beam is deflected by the blanker 6a and blocked by the blanking aperture 7, and thus is incident on the substrate 10. In this way, when the charged particle beams are switched on and off by the blanker 6a, a time period is required for charge to be accumulated in the capacitor 68 that is parallel-connected to the blanker 6a, and response lag (response delay) can occur before the charged particle beams are deflected by the blanker 6a. Specifically, the blanker 6a has an operating characteristic (transfer characteristic (transfer function)) in which an operating lag (operating delay) occurs when switching charged particle beams on and off, and a time period can be required between when a command value is supplied to the blanker and when the charged particle beams are switched on and off. For this reason, the change in the irradiation intensity of the charged particle beam on the substrate 10 is gradual in a pixel immediately after giving the blanker an instruction to switch the charged particle beam on or off. As a result, a difference can occur between the planned irradiation dose (command value) at that pixel and the actual irradiation dose (actual dose) at that pixel.

For example, envision a pixel irradiated with a charged particle beam immediately after giving the blanker an instruction to switch the charged particle beam from off to on, as with the third pixel from the left in FIG. 6. In this case, a dose of “10” in accordance with the command value is planned for the third pixel from the left. However, in actuality, a dose of only “6” can be obtained at that pixel due to the operating lag of the blanker 6a. Also, envision a pixel that is not to be irradiated with a charged particle beam immediately after giving the blanker an instruction to switch the charged particle beam from on to off, as with the sixth pixel from the left in FIG. 6. In this case, a dose of “0” in accordance with the command value is planned for the sixth pixel from the left. However, in actuality, a dose of only “4” can be obtained at that pixel due to the operating lag of the blanker 6a.

Also, the difference between the planned irradiation dose at a pixel and the actual irradiation dose at that pixel fluctuates according to the past charged particle beam control history. In the case where the switching on and off of the charged particle beam (state transition) occurs consecutively, the transition occurs in a state in which the voltage applied to the blanker 6a has not reached the maximum value, and therefore the difference between the planned irradiation dose and the actual dose at a pixel can increase even further. For example, take the tenth pixel from the left in FIG. 6. The command value for the tenth pixel is “0”, the command value for the immediately previous pixel (ninth pixel) is “10”, and the command value for the pixel two positions ahead (eighth pixel) is “0”. In other words, the charged particle beam state transition occurs consecutively. In this case, at the ninth pixel, the dose is “6” due to the operating lag of the blanker 6a, and the voltage applied to the blanker 6a does not reach the maximum value. Accordingly, at the tenth pixel, the charged particle beam irradiation intensity is reduced before reaching the maximum value, and the planned dose of “0” becomes a dose of “2”. Similarly, take the fifteenth pixel from the left in FIG. 6 for example. The command value for the fifteenth pixel is “10”, the command value for the immediately previous pixel (fourteenth pixel) is “0”, and the command value for the pixel two positions ahead (thirteenth pixel) is “10”. In other words, the charged particle beam state transition occurs consecutively. In this case, at the fourteenth pixel, the dose is “4” due to the operating lag of the blanker 6a, and the blanker voltage does not reach the minimum value. Accordingly, at the fifteenth pixel, the charged particle beam irradiation intensity is increased before reaching the minimum value, and the planned dose of “10” becomes a dose of “8”.

In this way, if an operating lag occurs in the blanker 6a when switching the charged particle beams on and off, immediately thereafter, a difference can arise between the planned irradiation dose (command value) at a pixel and the actual irradiation dose (actual dose) at that pixel. For this reason, if the command value is simply determined by binarizing (quantizing) the dose target value using a threshold value as in conventional drawing apparatuses, it is not necessarily the case that the command value can be determined so as to reduce the error between the target value and the actual dose value of the irradiated charged particle beam on the substrate 10. For example, envision the case of determining the command value at a target pixel for which the target value of the charged particle beam dose is “4”. In this case, in a conventional drawing apparatus, if the threshold value were set to “5”, the command value would be set to “0”, and the error between the command value and the target value would be “−4”. However, if the charged particle beam is off at the pixel before the target pixel, and then the charged particle beam is switched on at the target pixel, the actual charged particle beam dose value at the target pixel would be “6” due to the operating lag of the blanker 6a, and the error between this value and the target value would be “2”. Accordingly, in this case, if the threshold value were used, the command value for the target pixel would be determined so as to switch off the charged particle beam, but switching on the charged particle beam would reduce the absolute value of the error with respect to the target value. In other words, in a conventional method that uses a threshold value, it is not necessarily the case that the command value can be determined so as to reduce the error between the target value and the actual dose value of the irradiated charged particle beam on the substrate 10, and it has not been possible to form a pattern on the substrate 10 with sufficient precision.

In view of this, in the drawing apparatus 100 of the first embodiment, for each pixel on the substrate, taking into consideration the operating lag of the blanker 6a, the controller 100b predicts the irradiated charged particle beam dose at the pixel in both the case of instructing the switching on of the charged particle beam and the case of instructing the switching off of the charged particle beam. The controller 100b then determines the command value so as to achieve, out of these two cases, the case in which the absolute value of the difference between the predicted value and the target value for the charged particle beam dose is smaller (minimized).

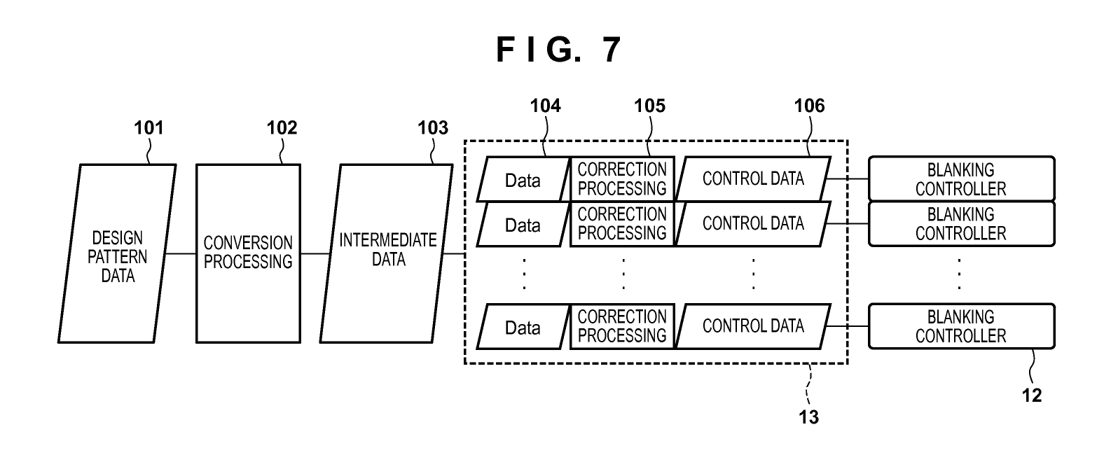

FIG. 7 is a diagram showing the flow of data in the drawing apparatus 100 of the first embodiment. This pattern data is vector design data (pattern data corresponding to a shot area that fits within 26 mm×33 mm) stored in the pattern data memory.

(1) Preparation Processing

First, in the data convertor 17, conversion processing 102 is performed to convert pattern data 101 into intermediate data 103. The data convertor 17 performs proximity effect correction on the pattern data 101, and changes the tones of the pattern data 101. The data resulting from the proximity effect correction is divided into units of stripes corresponding to the stripe drawing area SA. In the present embodiment, stitching is performed by performing double drawing (double exposure) with adjacent charged particle beams, and therefore a redundant area having a width of 0.1 μm is added to each side to generate intermediate data 103 having a width of 2.2 μm (the redundant portions of adjacent intermediate data can be the same data).

(2) Multivalue Processing

The following describes the flow of processing after the substrate 10 is introduced to the drawing apparatus 100. In the controller 100b, the main controller 19 transfers the intermediate data 103 from the intermediate data memory 18 to the data processor 13. The data processor 13 stores the transferred intermediate data 103 as pieces of multivalued pattern data (data 104) in units of stripes. These pieces of multivalued pattern data are data expressing target values for charged particle beam doses at pixels. Here, the vector intermediate data 103 is converted into multivalued pattern data pieces in the grid coordinate system of the drawing apparatus 100. Specifically, for example, conversion can be performed based on the area density of the intermediate data at the pixels, a correction coefficient that is based on the irradiation intensity of the charged particle beams for drawing the stripes, or the dose correction factor in the double drawing area (basically 0.5).

(3) Correction Processing

The data processor 13 performs correction processing 105 that includes the processes described in (3-1) to (3-3) below on the multivalued pattern data for each stripe, in parallel with drawing.

(3-1) Coordinate Transformation

In order to perform overlaid drawing in a shot area on a substrate, the data processor 13 performs coordinate transformation using Equation 1 based on information for obtaining the layout of the shot area on a substrate that has been measured in advance (e.g., a magnification coefficient βr, a rotation coefficient θr, and translation coefficients (shift coefficients) Ox and Oy). Here, x and y represent coordinates in the multivalued pattern data for each stripe before correction, and x′ and y′ represent coordinates in the multivalued pattern data for each stripe after correction. Also, Ox and Oy can include an offset amount for correcting positional shift from the designed positions of charged particle beams corresponding to a stripe.

$$( \begin{matrix}{x}^{′} \\ {y}^{′}\end{matrix} ) = ( \begin{matrix}Ox \\ Oy\end{matrix} ) + ( \begin{matrix}1 + βr & 0 \\ 0 & 1 + βr\end{matrix} ) ( \begin{matrix}1 & - θ r \\ θ r & 1\end{matrix} ) ( \begin{matrix}x \\ y\end{matrix} ) \qquad ( 1 )$$

(3-2) Binarization Processing

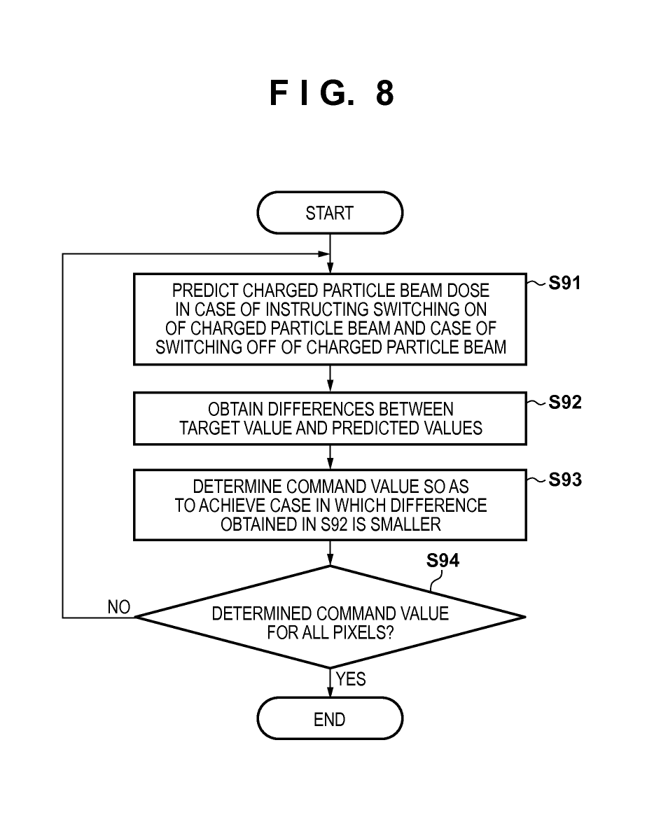

Processing for converting the multivalued pattern data resulting from the above-described coordinate transformation into binary pattern data (command values indicating the switching on and off of charged particle beams) will be described below with reference to FIG. 8. In step S91, taking into consideration the operating lag of the blanker 6a, the data processor 13 predicts the irradiated charged particle beam dose at a target pixel in both the case of instructing the switching on of the charged particle beam and the case of instructing the switching off of the charged particle beam. In step S92, the data processor 13 obtains the difference between the target value and the predicted value for the charged particle beam dose. In step S93, the data processor 13 determines the command value so as to achieve, out of the cases of instructing the switching on and off of the charged particle beam, the case in which the absolute value of the difference obtained in step S92 is smaller (minimized).

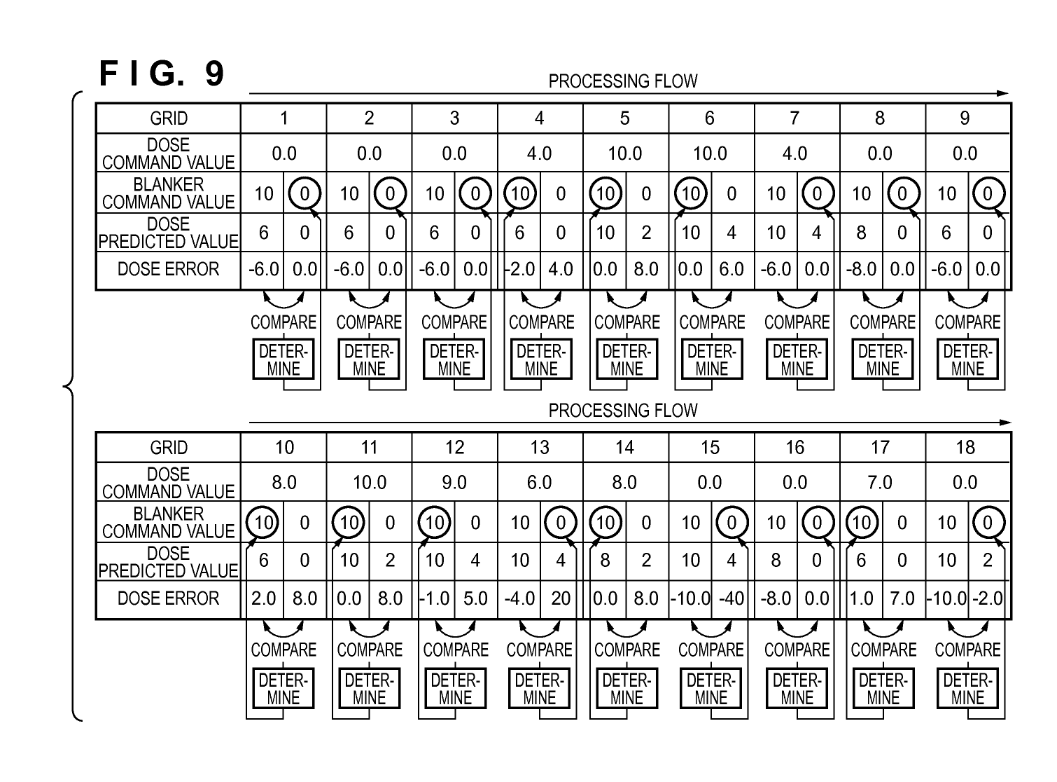

For example, envision the case where the target pixel is the fourth pixel from the left in FIG. 9. The command value is determined such that the charged particle beam is switched off at the pixel immediately previous to the target pixel and the pixel two positions ahead, and therefore at the target pixel, it is predicted that the irradiated charged particle beam dose at the target pixel will be “6” if the switching on of the charged particle beam is instructed. On the other hand, it is predicted that the irradiated charged particle beam dose at the target pixel will be “0” if the switching off of the charged particle beam is instructed. Accordingly, the absolute value of the difference between the predicted value and the target value “4” for the charged particle beam dose is smaller in the case of instructing the switching on of the charged particle beam, and the command value for the target pixel is determined to be “10”. Similarly, envision the case where the target pixel is the thirteenth pixel from the left in FIG. 9. The command value is determined such that the charged particle beam is switched on at the pixel immediately previous to the target pixel and the pixel two positions ahead, and therefore at the target pixel, it is predicted that the irradiated charged particle beam dose at the target pixel will be “10” if the switching on of the charged particle beam is instructed. On the other hand, it is predicted that the irradiated charged particle beam dose at the target pixel will be “4” if the switching off of the charged particle beam is instructed. Accordingly, the absolute value of the difference between the predicted value and the target value “6” for the charged particle beam dose is smaller in the case of instructing the switching off of the charged particle beam, and the command value for the target pixel is determined to be “0”.

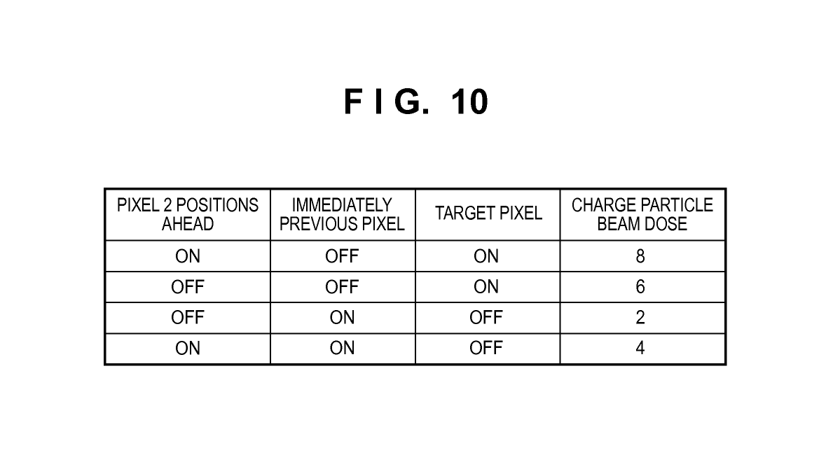

The prediction of the irradiated charged particle beam dose at the target pixel can be performed by, for example, referencing a look-up table that has been created in advance. For example, as shown in FIG. 10, this look-up table has information indicating the magnitude of the charged particle beam dose obtained at the target pixel as a result of controlling the charged particle beam at the target pixel, the pixel immediately previous to the target pixel, and the pixel two positions ahead of the target pixel. Specifically, the information shown in FIG. 10 is information indicating the relationship between command values and the dose at the target pixel in the case where the command values change between the target pixel and first pixels irradiated with a charged particle beam before the target pixel (including the immediately previous pixel and the pixel two positions ahead of the target pixel). By referencing this look-up table, the data processor 13 can predict the irradiated charged particle beam dose at the target pixel. The look-up table can be created by obtaining the operating lag of the blanker 6a through simulation or experimentation, for example. Here, in order to further improve precision, control of the charged particle beams at pixels three positions or more ahead of the target pixel may be taken into consideration when creating the look-up table. Also, although the drawing apparatus 100 of the first embodiment references the look-up table, predicts the irradiated charged particle beam dose at the target pixel, and determines command values for pixels before starting the drawing on the substrate 10, the present invention is not limited to this. For example, a configuration is possible in which the prediction of the dose at the target pixel and the determination of the command value are performed by real-time calculation when performing drawing.

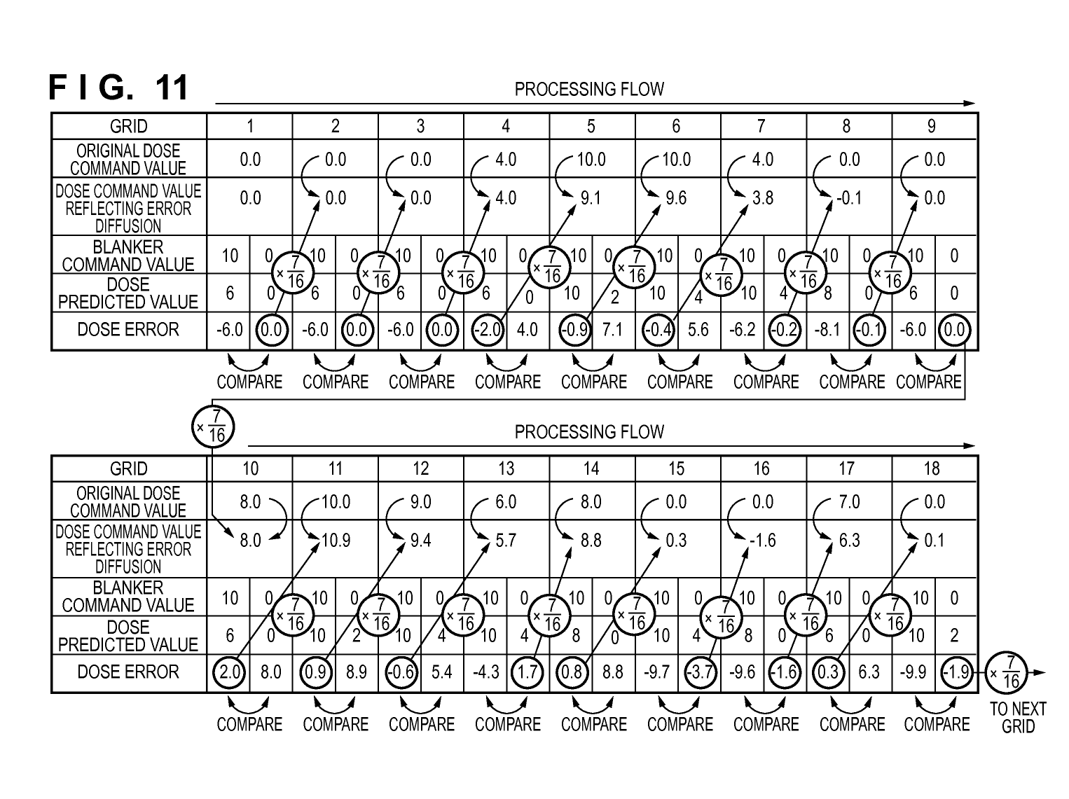

In step S94, the data processor 13 determines whether or not command values have been determined for all of the pixels. If command values have been determined for all of the pixels, the data processor 13 ends the processing for determining command values. On the other hand, if command values have not been determined for all of the pixels, the data processor 13 returns to step S91 and determines a command value for the next pixel. Here, using the example shown in FIG. 9, it was described that, taking into consideration the operating lag of the blanker 6a, the command value is determined by predicting the irradiated charged particle beam dose at the target pixel in both the case of instructing the switching on of the charged particle beam and the case of instructing the switching off of the charged particle beam. However, the present invention is not limited to this, and a configuration is possible in which, as shown in FIG. 11, out of the differences between the predicted value and the target value for the charged particle beam dose obtained in step S92, the difference with the smaller absolute value is diffused into the target value of the pixel that is to be irradiated with a charged particle beam after the target pixel. This step can be performed between steps S93 and S94. For example, in the case of the fourth pixel from the left in FIG. 11, the command value is determined such that the charged particle beam is switched on. For this reason, the data processor 13 diffuses the error “−2” between the predicted value and the target value for the charged particle beam dose into the pixel at the fifth or later position in accordance with an error diffusion method kernel such as that indicated by 55 in FIG. 5 or 56 in FIG. 5. FIG. 11 shows the example where the error is diffused using the Floyd & Steinberg error diffusion method kernel indicated by 55 in FIG. 5. Also, although the case of determining the command value (a binarized value) by binarizing the target value of the charged particle beam dose is described in the first embodiment, the present invention is not limited to this, and the command value (a quantized value) may be determined by performing multivalue processing on the target value to obtain 0, 5, and 10, for example.

(3-3) Serial Data Conversion

The data processor 13 generates control data 106 for the blankers by sorting the binarized data (command values) for the pixels for each charged particle beam and in the drawing order. The control data 106 generated in this way is successively sent to the blanking controller 12, and supplied to the blanker array 6 by the blanking controller 12.

As described above, for each pixel on the substrate, taking into consideration the operating lag of the blanker 6a, the drawing apparatus 100 of the first embodiment predicts the irradiated charged particle beam dose at the pixel in both the case of instructing the switching on of the charged particle beam and the case of instructing the switching off of the charged particle beam. The controller 100b then determines the command value so as to achieve, out of these two cases, the case in which the absolute value of the difference between the predicted value and the target value for the charged particle beam dose is smaller. Accordingly, error arising at the pixels can be reduced, thus making it possible to reduce position shift and blurring or slurring (e.g., shrinking line widths) in the pattern drawn on the substrate 10, and precisely form the pattern on the substrate 10.

Embodiment of Method of Manufacturing an Article

A method of manufacturing an article according to this embodiment of the present invention is favorable in, for example, manufacturing articles such as microdevices (e.g., semiconductor devices) and elements having a fine structure. The method of manufacturing an article of the present embodiment includes a step of forming a pattern on a substrate using the above-described lithography apparatus (drawing apparatus) (step of perform drawing on a substrate), and a step of processing the substrate on which the pattern was formed in the previous step. Furthermore, this manufacturing method includes other known steps (e.g., oxidation, film formation, vapor deposition, doping, planarization, etching, resist peeling, dicing, bonding, and packaging). The method of manufacturing an article of the present embodiment is advantageous over conventional methods in at least one of article performance, quality, productivity, and production cost.

For example, although the above description is given taking the example where the blanker array 6 includes an array of electrode pairs that can be driven individually, the present invention is not limited to this, and it is sufficient that the array has elements having a blanking function. For example, as disclosed in the specification of U.S. Pat. No. 7,816,655, the blanker array 6 can include a reflective electron patterning device that selectively reflects charged particle beams. This device includes a pattern on the top surface, an electron reflective portion of the pattern, and an electron non-reflective portion of the pattern. This device further includes an array of circuitry for dynamically varying the electron reflective and non-reflective portions of the pattern using independently-controllable pixels. In this way, the blanker array may be an array of elements (blankers) that perform charged particle beam blanking by changing charged particle beam reflective portions into non-reflective portions. Note that the configuration of the charged particle optical system that includes this reflective device can of course be different from the configuration of a charged particle optical system that includes a transmissive device for selectively transmitting charged particle beams as with an electrode pair array.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-093166 filed on Apr. 28, 2014, which is hereby incorporated by reference herein in its entirety.

What is claimed is:

1. A lithography apparatus that performs patterning on a substrate with a beam, the apparatus comprising:
a blanker configured to perform blanking of the beam; and
a controller configured to control the blanker based on a quantized value of dose with respect to each of pixels on the substrate,
wherein the controller is configured to determine the quantized value of dose with respect to each of the pixels based on an error between a target value of dose and each of a plurality of predicted values of dose that are based on a plurality of quantized values of dose.

2. The apparatus according to claim 1, wherein the controller is configured to determine the quantized value such that an absolute value of the error is minimized.

3. The apparatus according to claim 1, wherein the controller is configured to obtain the plurality of predicted value based on an operating characteristic of the blanker.

4. The apparatus according to claim 1, wherein the controller has information indicating a relationship between the dose at the target pixel and the plurality of quantized values in a case where all of the plurality of quantized values are not the same, and is configured to obtain each of the plurality of predicted values based on the information.

5. The apparatus according to claim 1, wherein the blanker includes one of a transmissive device configured to selectively transmit the beam, and a reflective device configured to selectively reflect the beam.

6. The apparatus according to claim 1, wherein the controller is configured to obtain, as the target value, a target value obtained by diffusing the error related to the determined quantized value.

7. The apparatus according to claim 1, wherein the controller is configured to obtain a binarized value as the quantized value.

8. The apparatus according to claim 1, wherein the patterning on the substrate is performed with a plurality of the beam, and the beam includes a charged particle beam.

9. The apparatus according to claim 1, wherein the controller is configured to obtain the target value based on an occupancy of a pattern, to be subjected to the patterning, in each of the pixels.

10. A method of manufacturing an article, the method comprising steps of:
performing patterning on a substrate using a lithography apparatus; and
processing the substrate, on which the patterning has been performed, to manufacture the article,
wherein the lithography apparatus performs patterning on the substrate with a beam, and includes:
a blanker configured to perform blanking of the beam; and
a controller configured to control the blanker based on a quantized value of dose with respect to each of pixels on the substrate,
wherein the controller is configured to determine the quantized value of dose with respect to each of the pixels based on an error between a target value of dose and each of a plurality of predicted values of dose that are based on a plurality of quantized values of dose.
